(19) United States
(12) Patent Application Publication
(10) Pub. No.: US 2005/0101147 A1
(43) Pub. Date: May 12, 2005

(54) Method for integrating a high-k gate dielectric in a transistor fabrication process

(75) Inventors: Catherine B. Labelle, Wappingers Falls, NY (US); Boon-Yong Ang, Cupertino, CA (US); Joong S. Jeon, Cupertino, CA (US); Allison K. Holbrook, San Jose, CA (US); Qi Xiang, San Jose, CA (US); Huicai Zhong, Wappinger Falls, NY (US)

Correspondence Address: FARJAMI & FARJAMI LLP, 26522 LA ALAMEDA AVENUE, SUITE 360, MISSION VIEJO, CA, 92691, US

(73) Assignee: Advanced Micro Devices, Inc.

(21) Appl. No.: 10/705,347

(22) Filed: Nov. 8, 2003

(51) Int. Cl. H01L 21/302; H01L 21/461

(52) U.S. Cl. 438/710

(57) ABSTRACT

According to one exemplary embodiment, a method for forming a field-effect transistor on a substrate, where the substrate includes a high-k dielectric layer situated over the substrate and a gate electrode layer situated over the high-k dielectric layer, comprises a step of etching the gate electrode layer and the high-k dielectric layer to form a gate stack, where the gate stack comprises a high-k dielectric segment situated over the substrate and a gate electrode segment situated over the high-k dielectric segment. According to this exemplary embodiment, the method further comprises performing a nitridation process on the gate stack. The nitridation process can be performed by, for example, utilizing a plasma to nitridate sidewalls of the gate stack, where the plasma comprises nitrogen. The nitridation process can cause nitrogen to enter the high-k dielectric segment and form an oxygen diffusion barrier in the high-k dielectric segment, for example.

### TECHNICAL FIELD

The present invention is generally in the field of semiconductor devices. More particularly, the present invention is in the field of fabrication of field effect transistors.

### BACKGROUND ART

As field effect transistors (“FET”), such as PFETs and NFETs, are scaled down in size, semiconductor manufactures have utilized gate dielectrics having a high dielectric constant (“high-k”) to improve FET performance and reliability. High-k gate dielectrics are desirable in small feature size technologies since conventional gate dielectrics, such as silicon dioxide, are too thin and they result in high tunneling current, as well as other problems, which decrease performance and reliability of FETs. However, problems can occur during integration of a high-k gate dielectric into a transistor fabrication process.

In a conventional transistor fabrication process incorporating a high-k gate dielectric, a gate stack can be formed by etching a gate electrode layer and a high-k dielectric layer situated between the gate electrode layer and a substrate in a gate etch process. The gate electrode layer, which can comprise a conductive material such as polysilicon, and the high-k dielectric layer, which can comprise zirconium oxide, hafnium oxide, or other high-k material, are typically etched by a plasma in a plasma etch chamber. However, during the plasma etch, the plasma can damage the sidewalls of the gate stack, including exposed portions of gate electrode and high-k dielectric segments. For example, the plasma can etch away a portion of the high-k dielectric material and can damage the chemical structure of the high-k dielectric. After the gate etch process, a wet clean process is generally performed on the gate stack to remove contaminants. However, the wet clean process can also damage the high-k dielectric by stripping off some of the high-k dielectric material. Additionally, oxygen can laterally diffuse into the high-k gate dielectric during subsequent process steps and alter the properties of the high-k dielectric material and the transistor gate.

Thus, there is a need in the art for an effective method for integrating a high-k gate dielectric in a transistor fabrication process.

### SUMMARY

The present invention addresses and resolves the need in the art for an effective method for integrating a high-k gate dielectric in a transistor fabrication process.

According to one exemplary embodiment, a method for forming a field-effect transistor on a substrate, where the substrate includes a high-k dielectric layer situated over the substrate and a gate electrode layer situated over the high-k dielectric layer, comprises a step of etching the gate electrode layer and the high-k dielectric layer to form a gate stack, where the gate stack comprises a high-k dielectric segment situated over the substrate and a gate electrode segment situated over the high-k dielectric segment. The high-k dielectric segment may be, for example, hafnium oxide, hafnium silicate, zirconium oxide, zirconium silicate, or aluminum oxide and the gate electrode segment can be polysilicon.

According to this exemplary embodiment, the method further comprises performing a nitridation process on the gate stack. The nitridation process can be performed by, for example, utilizing a plasma to nitridate sidewalls of the gate stack, where the plasma comprises nitrogen. The nitridation process can cause nitrogen to enter the high-k dielectric segment and form an oxygen diffusion barrier in the high-k dielectric segment, for example. The step of etching the gate electrode layer and the high-k dielectric layer can be performed in a process chamber, where the process chamber is also utilized to perform the nitridation process on the gate stack, for example. In one embodiment, the step of etching the gate electrode layer and the high-k dielectric layer is performed in a first process chamber and the step of performing the nitridation process on the gate stack is performed in a second process chamber. Other features and advantages of the present invention will become more readily apparent to those of ordinary skill in the art after reviewing the following detailed description and accompanying drawings.

### BRIEF DESCRIPTION OF THE DRAWINGS

FIG. 1 illustrates a cross-sectional view of a structure including an exemplary transistor gate stack, in accordance with one embodiment of the present invention.

FIG. 2 is a flowchart corresponding to exemplary method steps according to one embodiment of the present invention.

### DETAILED DESCRIPTION OF THE INVENTION

The present invention is directed to method for integrating a high-k gate dielectric in a transistor fabrication process. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings.

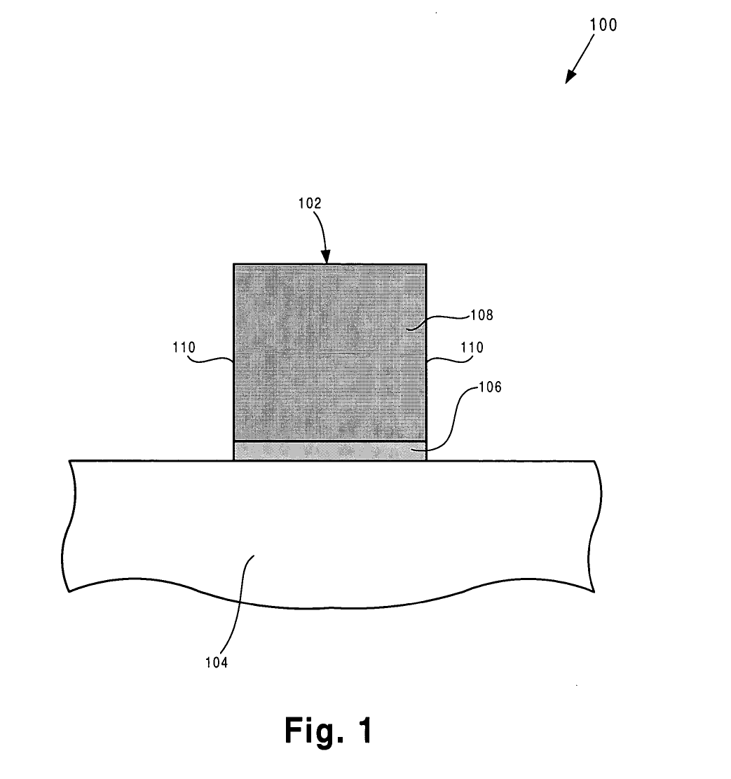

FIG. 1 shows a cross-sectional view of an exemplary structure including an exemplary gate stack in accordance with one embodiment of the present invention. Structure 100 includes gate stack 102, which is situated on substrate 104. Gate stack 102 includes high-k dielectric segment 106 and gate electrode segment 108 and has sidewalls 110. In one embodiment, gate stack 102 can include an interfacial layer (not shown in FIG. 1) situated between high-k dielectric segment 106 and substrate 104. Structure 100 illustrates an intermediate step in a transistor process flow that is utilized to form a FET, such as an NFET or PFET, which includes gate stack 102.

As shown in FIG. 1, high-k dielectric segment 106 is situated over substrate 104 and can comprise a high-k dielectric, such as hafnium oxide, hafnium silicate, zirconium oxide, zirconium silicate, or aluminum oxide. It is noted that the high-k dielectrics mentioned above and in other parts of the present application are merely specific examples, while other high-k dielectrics could also be employed and the present invention is by no means limited to the use of only those high-k dielectrics mentioned herein. By way of a further example, high-k dielectric segment 106 can have a thickness of between approximately 20.0 Angstroms and approximately 100.0 Angstroms. Also shown in FIG. 1, gate electrode segment 108 is situated over high-k dielectric segment 106 and can comprise polysilicon. By way of example, gate electrode segment 108 can have a thickness of between approximately 500.0 Angstroms and approximately 1500.0 Angstroms.

Gate stack 102, which includes high-k dielectric segment 106 and gate electrode segment 108, can be formed by etching a high-k dielectric layer and a gate electrode layer, respectively, in a gate etch process. Prior to the gate etch process, the high-k dielectric layer can be formed over substrate 104 and the gate electrode layer can be formed over the high-k dielectric layer in a manner known in the art. In the gate etch process, for example, the high-k dielectric layer and the gate electrode layer can be etched in a process chamber by utilizing a plasma etch. In the transistor process flow of the present invention, after gate stack 102 has been formed, a nitridation process is performed on gate stack 102. The nitridation process can be performed by utilizing a plasma comprising nitrogen, i.e. a nitrogen plasma, to nitridate exposed surfaces of gate stack 102, such as sidewalls 110. The nitridation process can be performed in the same process chamber that is utilized to form gate stack 102 in the gate etch process discussed above. In one embodiment, the nitridation process can be performed in a different process chamber than the one (i.e. the process chamber) utilized to perform the gate etch process. In such embodiment, after the gate etch process, the wafer comprising gate stack 102 is removed from the process chamber utilized to perform the gate etch process and a wet clean process is performed on the wafer in a wet clean tool. The wafer comprising gate stack 102 is then placed in another process chamber, where the nitridation process is performed on gate stack 102. In one embodiment, the nitridation process can be performed on gate stack 102 immediately after the gate etch process has been performed.

By performing the nitridation process to nitridate sidewalls 110 of gate stack 102 after the gate etch process has been performed, the present invention's process flow can utilize the nitridation process to repair damage that may occur to gate stack 102 during the gate etch process. Additionally, during the nitridation process, nitrogen is introduced into high-k dielectric segment 106. As a result, the nitrogen that is introduced into high-k dielectric segment 106 can form a barrier that can prevent undesirable lateral oxygen diffusion into high-k dielectric segment 106 during subsequent processing steps. In an embodiment of the present invention that utilizes a gate stack comprising an interfacial layer, where the interfacial layer comprises nitride, the nitridation process can replace nitride that has been depleted in the interfacial layer during the gate etch process.

After performance of the nitridation process, the present invention's transistor process flow continues in a similar manner as a conventional transistor process flow. For example, source/drain regions can be implanted in substrate 104 adjacent to gate stack 102, spacers can be formed adjacent to sidewalls 110 of gate stack 102, a rapid thermal anneal process can be performed, as well as other process steps required to complete fabrication of a transistor, such as a FET.

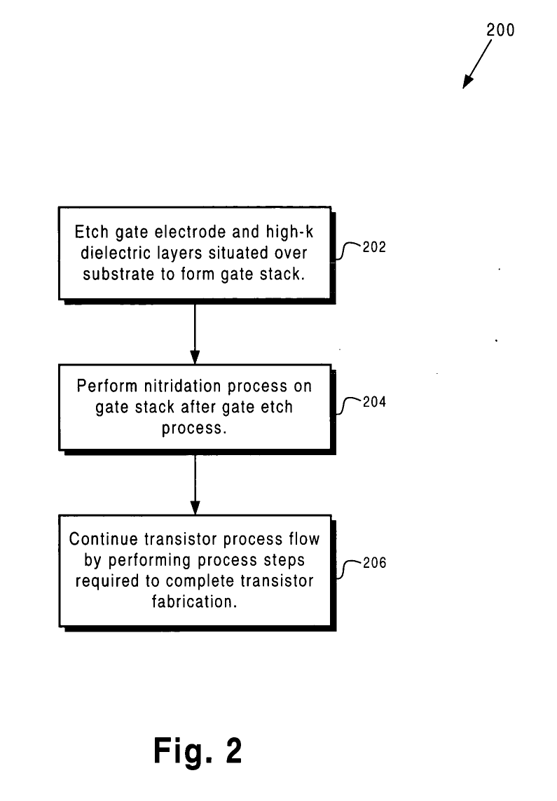

FIG. 2 shows a flowchart illustrating an exemplary method according to one embodiment of the present invention. Certain details and features have been left out of flowchart 200 that are apparent to a person of ordinary skill in the art. For example, a step may consist of one or more substeps or may involve specialized equipment or materials, as known in the art. At step 202 of flowchart 200, a high-k dielectric layer situated over a substrate and a gate electrode layer situated over the high-k dielectric layer are etched to form a gate stack. For example, gate stack 102, which includes high-k dielectric segment 106 situated over substrate 104 and gate electrode segment 108 situated over high-k dielectric segment 106, can be formed by appropriately etching the gate electrode layer and the high-k dielectric layer by utilizing a plasma etch in a gate etch process.

At step 204, a nitridation process is performed on the gate stack after the gate etch process has been performed. For example, the nitridation process can be performed on gate stack 102 after the gate etch process by utilizing a nitrogen plasma to nitridate sidewalls 110 of gate stack 102. The nitridation process can be performed, for example, in the same process chamber that is utilized to perform the gate etch process. In one embodiment, a process chamber that is different from the one (i.e., the process chamber) utilized to perform the gate etch process can be utilized to perform the nitridation process. At step 206, the transistor process flow is continued by performing process steps required to complete transistor fabrication. For example, source/drain regions can be implanted in substrate 104 adjacent to gate stack 102, spacers can be formed adjacent to sidewalls 110 of gate stack 102, and other appropriate processing steps can be performed to complete fabrication of a transistor, such as a FET.

Thus, as discussed above, by performing a nitridation process after a gate etch process, the present invention's process flow can utilize the nitridation process to repair damage that may occur to the gate stack sidewalls during the gate etch process. Additionally, the present invention's nitridation process introduces nitrogen into the high-k dielectric segment of the gate stack such that the nitrogen forms a barrier that can prevent undesirable lateral oxygen diffusion into the high-k dielectric segment during subsequent process steps.

From the above description of exemplary embodiments of the invention it is manifest that various techniques can be used for implementing the concepts of the present invention without departing from its scope. Moreover, while the invention has been described with specific reference to certain embodiments, a person of ordinary skill in the art would recognize that changes could be made in form and detail without departing from the spirit and the scope of the invention. The described exemplary embodiments are to be considered in all respects as illustrative and not restrictive. It should also be understood that the invention is not limited to the particular exemplary embodiments described herein, but is capable of many rearrangements, modifications, and substitutions without departing from the scope of the invention.

Thus, method for integrating a high-k gate dielectric in a transistor fabrication process has been described.

1. A method for forming a field-effect transistor on a substrate, said substrate including a high-k dielectric layer situated over said substrate and a gate electrode layer situated over said high-k dielectric layer, said method comprising steps of:
etching said gate electrode layer and said high-k dielectric layer to form a gate stack, said gate stack comprising a high-k dielectric segment situated over said substrate and a gate electrode segment situated over said high-k dielectric segment;
performing a nitridation process on said gate stack.

2. The method of claim 1 wherein said step of performing said nitridation process on said gate stack comprises utilizing a plasma to nitridate sidewalls of said gate stack, said plasma comprising nitrogen.

3. The method of claim 1 wherein said step of performing said nitridation process on said gate stack causes nitrogen to enter said high-k dielectric segment, said nitrogen forming an oxygen diffusion barrier in said high-k dielectric segment.

4. The method of claim 1 wherein said step of etching said gate electrode layer and said high-k dielectric layer to form said gate stack is performed in a process chamber, said process chamber being utilized to perform said step of performing said nitridation process on said gate stack.

5. The method of claim 1 wherein said step of etching said gate electrode layer and said high-k dielectric layer to form said gate stack is performed in a first process chamber and said step of performing said nitridation process on said gate stack is performed in a second process chamber.

6. The method of claim 1 wherein said high-k dielectric segment is selected from the group consisting of hafnium oxide, hafnium silicate, zirconium oxide, zirconium silicate, and aluminum oxide.

7. The method of claim 1 wherein said gate electrode segment comprises polysilicon.

8. A method for forming a field-effect transistor on a substrate, said substrate including a high-k dielectric layer situated over said substrate and a gate electrode layer situated over said high-k dielectric layer, said method comprising a step of etching said gate electrode layer and said high-k dielectric layer to form a gate stack, said gate stack comprising a high-k dielectric segment situated over said substrate and a gate electrode segment situated over said high-k dielectric segment, said method being characterized by:
performing a nitridation process on said gate stack.

9. The method of claim 8 wherein said step of performing said nitridation process on said gate stack comprises utilizing a plasma to nitridate sidewalls of said gate stack, said plasma comprising nitrogen.

10. The method of claim 8 wherein said step of performing said nitridation process on said gate stack causes nitrogen to enter said high-k dielectric segment, said nitrogen forming an oxygen diffusion barrier in said high-k dielectric segment.

11. The method of claim 8 wherein said step of etching said gate electrode layer and said high-k dielectric layer to form said gate stack is performed in a process chamber, said process chamber being utilized to perform said step of performing said nitridation process on said gate stack.

12. The method of claim 8 wherein said step of etching said gate electrode layer and said high-k dielectric layer to form said gate stack is performed in a first process chamber and said step of performing said nitridation process on said gate stack is performed in a second process chamber.

13. The method of claim 8 wherein said high-k dielectric segment is selected from the group consisting of hafnium oxide, hafnium silicate, zirconium oxide, zirconium silicate, and aluminum oxide.

14. The method of claim 8 wherein said gate electrode segment comprises polysilicon.

15. A method for forming a field-effect transistor on a substrate, said substrate including a high-k dielectric layer situated over said substrate and a gate electrode layer situated over said high-k dielectric layer, said method comprising steps of:
etching said gate electrode layer and said high-k dielectric layer to form a gate stack, said gate stack comprising a high-k dielectric segment situated over said substrate and a gate electrode segment situated over said high-k dielectric segment, said gate stack comprising sidewalls;
utilizing a nitrogen plasma to nitridate said sidewalls of said gate stack.

16. The method of claim 15 wherein said step of utilizing said nitrogen plasma to nitridate said sidewalls of said gate stack causes nitrogen to enter said high-k dielectric segment, said nitrogen forming an oxygen diffusion barrier in said high-k dielectric segment.

17. The method of claim 15 wherein said step of etching said gate electrode layer and said high-k dielectric layer to form said gate stack is performed in a process chamber, said process chamber being utilized to perform said step of utilizing a nitrogen plasma to nitridate said sidewalls of said gate stack.

18. The method of claim 15 wherein said step of etching said gate electrode layer and said high-k dielectric layer to form said gate stack is performed in a first process chamber and said step of utilizing a nitrogen plasma to nitridate said sidewalls of said gate stack is performed in a second process chamber.

19. The method of claim 15 wherein said high-k dielectric segment is selected from the group consisting of hafnium oxide, hafnium silicate, zirconium oxide, zirconium silicate, and aluminum oxide.

20. The method of claim 15 wherein said gate electrode segment comprises polysilicon.
